(19) United States
(12) Patent Application Publication
(10) Pub. No.: US 2025/0199077 A1
(43) Pub. Date: Jun. 19, 2025

(54) ONLINE ESTIMATION OF CURRENT-DEPENDENT NON-LINEAR EQUIVALENT CIRCUIT MODEL PARAMETERS OF A BATTERY USING AUGMENTED HIGH-CURRENT STIMULUS

(71) Applicant: Cirrus Logic International Semiconductor Ltd., Edinburgh (GB)

(72) Inventors: Samuel P. EBENEZER, Gilbert, AZ (US); Seth SUPPAPPOLA, Tempe, AZ (US); Eric J. KING, Austin, TX (US); Ilija JERGOVIC, Austin, TX (US); Ravi K. KUMMARAGUNTLA, Austin, TX (US); Rachid KERKOUD, Gilbert, AZ (US)

(73) Assignee: Cirrus Logic International Semiconductor Ltd., Edinburgh (GB)

(21) Appl. No.: 19/064,389

(22) Filed: Feb. 26, 2025

Related U.S. Application Data
(63) Continuation-in-part of application No. 18/828,879, filed on Sep. 9, 2024.
(60) Provisional application No. 63/606,389, filed on Dec. 5, 2023.

(51) Int. Cl. G01R 31/367; G01R 31/3842; G01R 31/389; H02J 7/00; H02J 7/34

(52) U.S. Cl. CPC G01R 31/367; G01R 31/3842; G01R 31/389; H02J 7/00714; H02J 7/007182; H02J 7/342

(57) ABSTRACT

A method for estimating current-dependent non-linear equivalent circuit model (ECM) parameters of a battery may include measuring a battery voltage across terminals of the battery and a battery current drawn from the battery, modelling behavior of the battery with an impedance model having impedance model parameters, dynamically analyzing the battery current drawn from the battery by a load, dynamically determining safe operating limits for an augmented current for augmenting the current drawn by the load, based on analysis of the battery current and the safe operating limits, determining the augmented current, generating the augmented current to be drawn from the battery, and estimating the impedance model parameters when the augmented current is drawn from the battery.

### RELATED APPLICATIONS

The present disclosure claims priority as a continuation-in-part to U.S. patent application Ser. No. 18/828,879, filed Sep. 9, 2024, which in turn claims priority to U.S. Provisional Patent Application Ser. No. 63/606,389, filed Dec. 5, 2023, both of which are incorporated by reference herein in their entireties.

The present disclosure is also related to U.S. patent application Ser. No. 18/308,420, filed Apr. 27, 2023, U.S. patent application Ser. No. 18/308,449, filed Apr. 27, 2023, U.S. patent application Ser. No. 18/455,253, filed Aug. 24, 2023, and U.S. patent application Ser. No. 18/628,374, filed Apr. 5, 2024, all of which are incorporated by reference herein in their entireties.

### FIELD OF DISCLOSURE

The present disclosure relates in general to circuits for electronic devices, including without limitation personal portable devices such as wireless telephones and media players, and more specifically, to online characterization of battery model parameters with augmented dynamic stimulus and estimation of equivalent circuit model parameters of a battery.

### BACKGROUND

Portable electronic devices, including wireless telephones, such as mobile/cellular telephones, tablets, cordless telephones, mp3 players, and other consumer devices, are in widespread use. Such a portable electronic device may include a battery (e.g., a lithium-ion battery) for powering components of the portable electronic device.

In operation, the terminal voltage of a battery may droop under a load current due to internal output impedance of the battery. Such output impedance may be modeled in a number of suitable manners, including with an equivalent circuit model of a series of parallel-coupled resistors and capacitors. Knowledge of the detailed impedance of a battery may be useful for fuel-gauging algorithms (e.g., for determining a battery open-circuit voltage and state of charge, predicting power limits, and/or deriving safety limits or safe operation limits of the battery (e.g., a maximum voltage and maximum current of the battery terminal)).

There may exist advantages in using a system load current drawn from a battery in order to perform in-situ characterization of parameters of the equivalent circuit model, as such an approach avoids time-consuming and computationally-expensive offline characterization that measures impedance of a battery across a frequency range. Offline characterization may also not generalize well, because variations in device usage behavior may affect age-dependent impedance. Moreover, a battery is a highly non-linear dynamic system, and the offline characterization will not work well under various working conditions of the battery. However, spectrally-rich stimulus may be required to accurately estimate equivalent circuit model parameters, and system load current is not guaranteed to contain spectrally-rich content at all times. Further, the battery behavior may change as a function of the load current amplitude. It may not be possible to model this non-linear behavior through a linear equivalent circuit model (ECM) of the battery. The ECM parameters may have to be adjusted as a function of the load current amplitude. However, it may not be possible to estimate these current level-dependent model parameters if high load current is not drawn from the battery.

### SUMMARY

In accordance with the teachings of the present disclosure, one or more disadvantages and problems associated with existing approaches to modeling a battery (e.g., with an equivalent circuit model or physics-based model) may be reduced or eliminated.

In accordance with embodiments of the present disclosure, a method for estimating current-dependent non-linear equivalent circuit model (ECM) parameters of a battery may include measuring a battery voltage across terminals of the battery and a battery current drawn from the battery, modelling behavior of the battery with an impedance model having impedance model parameters, dynamically analyzing the battery current drawn from the battery by a load, dynamically determining safe operating limits for an augmented current for augmenting the current drawn by the load, based on analysis of the battery current and the safe operating limits, determining the augmented current, generating the augmented current to be drawn from the battery, and estimating the impedance model parameters when the augmented current is drawn from the battery.

In accordance with these and other embodiments of the present disclosure, a system for estimating current-dependent non-linear equivalent circuit model (ECM) parameters of a battery may include measurement circuitry for measuring a battery voltage across terminals of the battery and a battery current drawn from the battery, an impedance model having impedance model parameters, the impedance model for modelling behavior of the battery, and an augmented stimulus signal generator configured to dynamically analyze the battery current drawn from the battery by a load, dynamically determine safe operating limits for an augmented current for augmenting the current drawn by the load, based on analysis of the battery current and the safe operating limits, determine the augmented current, and generate the augmented current to be drawn from the battery. The system may also include a battery model estimator for estimating the impedance model parameters when the augmented current is drawn from the battery.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example power delivery network, in accordance with embodiments of the present disclosure;

FIG. 2 illustrates an example graph of an open circuit voltage of a battery versus the battery's state of charge, in accordance with embodiments of the present disclosure;

FIG. 3 illustrates a circuit diagram of selected components of an equivalent circuit model for a battery, in accordance with embodiments of the present disclosure;

FIG. 4 illustrates a block diagram of a system for online characterization of an equivalent circuit model of a battery using sub-bands and augmented dynamic current stimulus, in accordance with embodiments of the present disclosure;

FIGS. 5A and 5B illustrate a block diagram of an example architecture of an algorithm for calculating parameters of an equivalent circuit model of a battery, in accordance with embodiments of the present disclosure;

FIG. 6 illustrates a block diagram of an example architecture of a tracker for calculating parameters of an equivalent circuit model of a battery, in accordance with embodiments of the present disclosure;

FIG. 7 illustrates a block diagram of selected components of a system for online characterization of an equivalent circuit model of a battery using sub-bands and augmented dynamic current stimulus, in accordance with embodiments of the present disclosure;

FIG. 8 illustrates a high-level block diagram of selected components of a system for online characterization of a current-dependent non-linear equivalent circuit model of a battery, in accordance with embodiments of the present disclosure;

FIG. 9 illustrates a detailed-level block diagram of selected components of a system for online characterization of a current-dependent non-linear equivalent circuit model of a battery, in accordance with embodiments of the present disclosure;

FIG. 10 illustrates a circuit diagram of selected components of a subsystem for generating an augmented current, in accordance with embodiments of the present disclosure;

FIG. 11 illustrates a circuit diagram of selected components of another subsystem for generating an augmented current, in accordance with embodiments of the present disclosure;

FIG. 12 illustrates a circuit diagram of selected components of yet another subsystem for generating an augmented current, in accordance with embodiments of the present disclosure; and

FIG. 13 illustrates a block diagram of selected components of an example power delivery network, in accordance with embodiments of the present disclosure.

### DETAILED DESCRIPTION

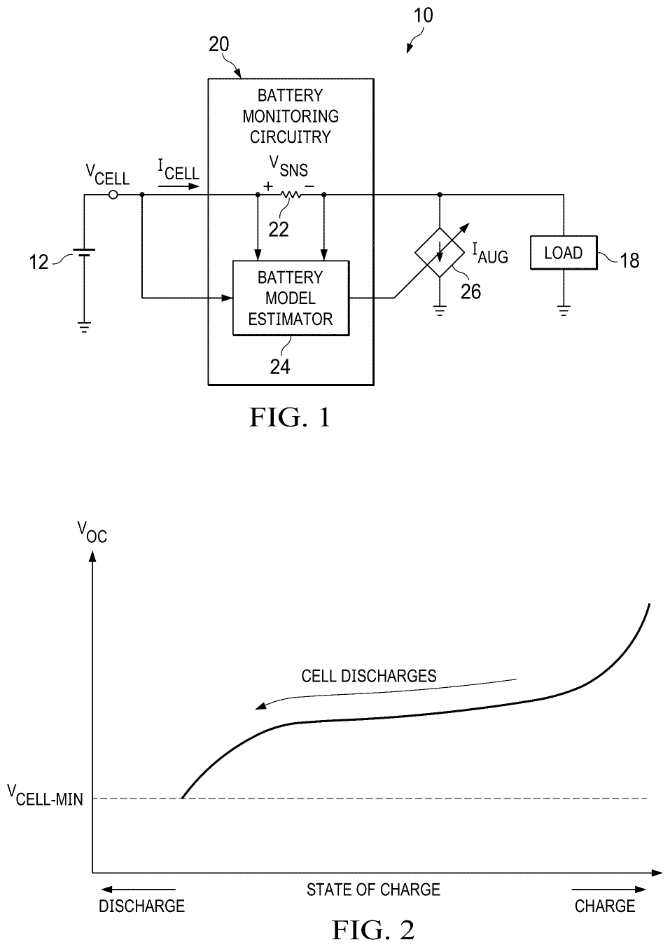

FIG. 1 illustrates a block diagram of selected components of an example power delivery network 10, in accordance with embodiments of the present disclosure. In some embodiments, power delivery network 10 may be implemented within a portable electronic device, such as a smart phone, tablet, game controller, and/or other suitable device.

As shown in FIG. 1, power delivery network 10 may include a battery 12 and a load 18. As shown in FIG. 1, when loaded by load 18, battery 12 may generate a battery voltage V_{CELL} across its terminals and deliver a battery current I_{CELL} to load 18. In some embodiments, battery 12 may comprise a lithium-ion battery. Load 18 may represent any electric component, electronic component, and/or combination thereof. For example, load 18 may include any suitable functional circuits or devices of power delivery network 10, including without limitation power converters, processors, audio coder/decoders, amplifiers, display devices, etc. Further, although not explicitly shown in FIG. 1, power delivery network 10 may also include control circuitry for controlling operation of battery 12 and/or load 18.

As also shown in FIG. 1, power delivery network 10 may include battery monitoring circuitry 20. Battery monitoring circuitry 20 may include any suitable system, device, or apparatus configured to monitor battery voltage V_{CELL} and battery current I_{CELL}.

Further, battery monitoring circuitry 20 may include a battery model estimator 24 configured to monitor battery voltage V_{CELL} and a sense voltage V_{SNS} across a sense resistor 22 indicative of battery current I_{CELL}, and based thereon, estimate a battery impedance model for battery 12, as described in greater detail below. Battery model estimator 24 may be implemented with a processing device, including without limitation a microprocessor, digital signal processor, application-specific integrated circuit, field-programmable gate array, electrically-erasable programmable read only memory, complex programmable logic device, and/or other suitable processing device. In some embodiments, battery monitoring circuitry 20 may monitor a temperature associated with battery 12, and battery model estimator 24 may estimate the impedance model based on battery voltage V_{CELL}, a sense voltage V_{SNS}, and the sensed temperature.

As further shown in FIG. 1, power delivery network 10 may further include a dependent current source 26 controlled by battery model estimator 24 and configured to generate an augmented current I_{AUG}. Control of augmented current I_{AUG} by battery model estimator 24 is described in greater detail below.

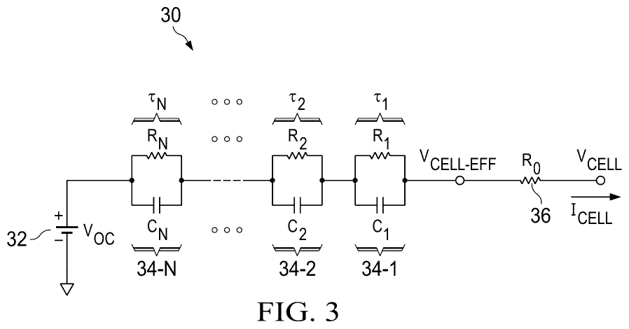

Lithium-ion batteries are typically known to operate from 4.5 V down to 3.0 V, known as an open circuit voltage V_{OC} of the battery (e.g., battery 12). As a battery discharges due to a current drawn from the battery, the state of charge of the battery may also decrease, and open circuit voltage V_{OC} (which may be a function of state of charge) may also decrease as a result of electrochemical reactions taking place within the battery, as shown in FIG. 2. Outside the range of 3.0 V and 4.5 V for open circuit voltage V_{OC}, the capacity, life, and safety of a lithium-ion battery may degrade. For example, at approximately 3.0 V, approximately 95% of the energy in a lithium-ion cell may be spent, and open circuit voltage V_{OC} would be liable to drop rapidly if further discharge were to continue. Below approximately 2.4 V, metal plates of a lithium-ion battery may erode, which may cause higher internal impedance for the battery, lower capacity, and potential short circuit. Thus, to protect a battery (e.g., battery 12) from over-discharging, many portable electronic devices may prevent operation below a predetermined end-of-discharge voltage. Knowledge of the output impedance may be useful in determining open circuit voltage V_{OC} and other parameters of battery 12.

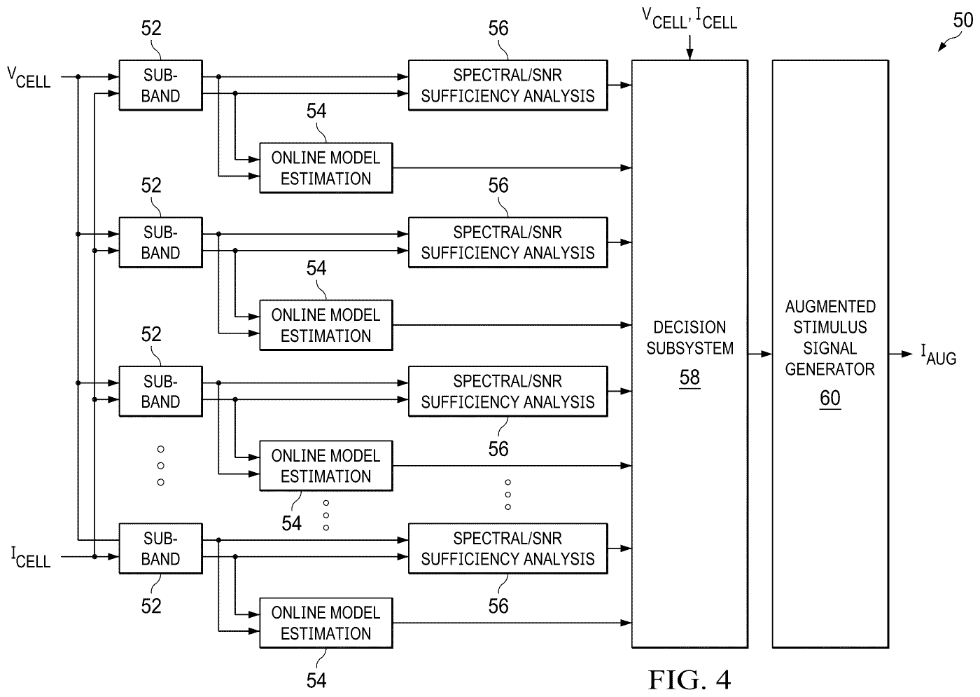

FIG. 3 illustrates a block diagram of selected components of an equivalent circuit model 30 for battery 12, in accordance with embodiments of the present disclosure. As shown in FIG. 3, battery 12 may be modeled as having a battery cell 32 having an open circuit voltage V_{OC} in series with a plurality of parallel resistive-capacitive sections 34 (e.g., parallel resistive-capacitive sections 34-1, 34-2, . . . , 34-N) and further in series with an equivalent series resistance 36 of battery 12, such equivalent series resistance 36 having a resistance of R₀. Resistances R₁, R₂, . . . R_{N}, and respective capacitances C₁, C₂, . . . , C_{N} may model battery chemistry-dependent time constants τ₁, τ₂, . . . , τ_{N}, that may be lumped with open circuit voltage V_{OC} and equivalent series resistance 36. The series of impedance sections represented by resistive-capacitive sections 34 and equivalent series resistance 36 may represent diffusion processes that occur at different rates inside battery 12. Cutoff frequencies of parallel resistive-capacitive sections 34 may respectively be given by:

$${f}_{c 1} = \frac{1}{{τ}_{1}} = \frac{1}{2 π {R}_{1} {C}_{1}} ; \\ {f}_{c 2} = \frac{1}{{τ}_{2}} = \frac{1}{2 π {R}_{2} {C}_{2}} ; \\ … \\ {f}_{cN} = \frac{1}{{τ}_{N}} = \frac{1}{2 π {R}_{N} {C}_{N}} ;$$

wherein π represents the well-known mathematical constant defined as the ratio of a circle's circumference to its diameter, and wherein parallel resistive-capacitive sections 34 are ordered such that f_{cN}< . . . <f_{c2}<f_{c1}.

Notably, an electrical node depicted with voltage V_{CELL-EFF} in FIG. 3 may capture the time varying discharge behavior of battery 12, and battery voltage V_{CELL} may be an actual voltage seen across the output terminals of battery 12. Voltage V_{CELL-EFF} may not be directly measurable, and thus battery voltage V_{CELL} may be the only voltage associated with battery 12 that may be measured to evaluate battery state of health. Also of note, at a current draw of zero (e.g., I_{CELL}=0), battery voltage V_{CELL} may be equal to voltage V_{CELL-EFF} which may in turn be equal to an open circuit voltage V_{OC} at a given state of charge, provided that enough time has passed with the current at zero, such that all of the voltages on capacitors of resistive-capacitive sections 34 have discharged to zero.

Battery behavior may change due to various factors, including temperature, state of charge, charge/discharge current amplitude and/or frequency, and others. Changes in such factors may change electro-chemical states of the battery, and these dynamic behaviors may result in corresponding changes in parameter values of the equivalent circuit model 30. Parameters of the equivalent circuit model 30 may be used to assess battery condition, predict future voltage, and/or other battery management tasks.

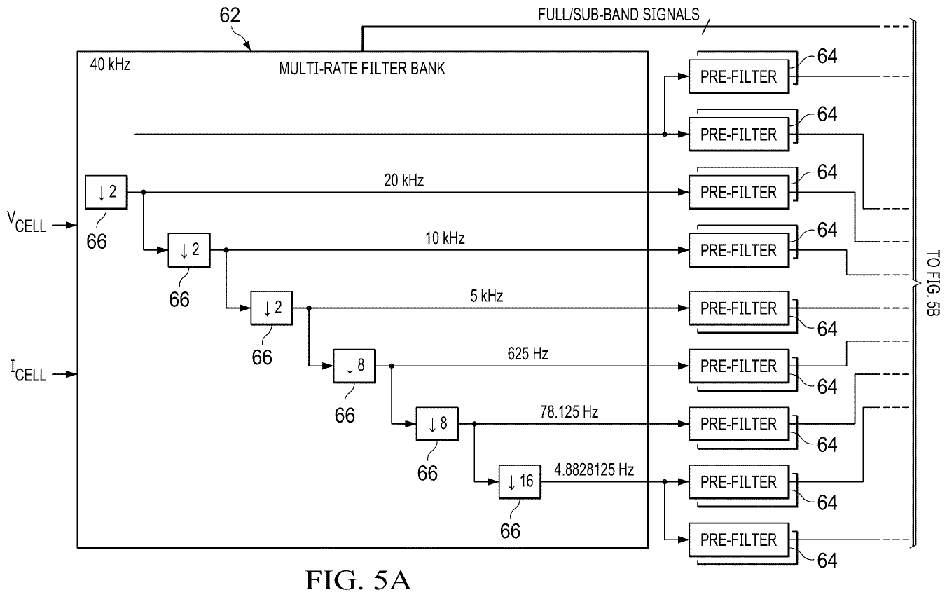

FIG. 4 illustrates a block diagram of a system 50 for online characterization of an equivalent circuit model 30 of battery 12 using sub-bands and augmented dynamic current stimulus, in accordance with embodiments of the present disclosure. System 50 may be implemented as or as a part of battery model estimator 24.

To estimate an impedance model of battery 12, battery model estimator 24 may divide the output impedance of battery 12 into a number of stages or frequency sub-bands 52, each stage/sub-band 52 corresponding to a respective parallel resistive-capacitive section 34 of the equivalent circuit model, thus breaking down the online model estimation 54 into several identification problems of lower order. Such estimation in stages may be possible due to the fact that cutoff frequencies f_{E} (or time constants τ) of the various parallel resistive-capacitive sections, which represent the various electro-chemical processes that occur over different time durations and which represent different electro-chemical processes that happen at a different rate of speed, may be separated by an order of magnitude or more. Further, battery model estimator 24 may, for each particular frequency sub-band 52, monitor, with spectral/signal-to-noise ratio (SNR) sufficiency analysis 56, the quality of prevailing current stimulus I_{CELL} drawn from battery 12 over time and monitor variance of the various equivalent circuit model parameters for such sub-band. Battery model estimator 24 may further implement a decision subsystem 58 that may analyze online model estimations 54 for each sub-band 52, and results of the spectral/SNR analysis 56 for each sub-band 52, to decide whether to generate augmented current stimulus for a particular sub-band 52. If decision subsystem 58 determines to generate augmented current stimulus for a particular sub-band 52, augmented stimulus signal generator 60 may generate an augmented current I_{AUG} to supplement current drawn by load 18 in order to draw battery current I_{CELL} with sufficient spectral content to characterize parameters of the equivalent circuit model of battery 12. Augmented current I_{AUG} may be based on a dynamic analysis of battery current I_{CELL} and may also be based on an SNR and/or spectral requirement for the equivalent circuit model estimation algorithm performed by battery model estimator 24, in addition to other system-related requirements.

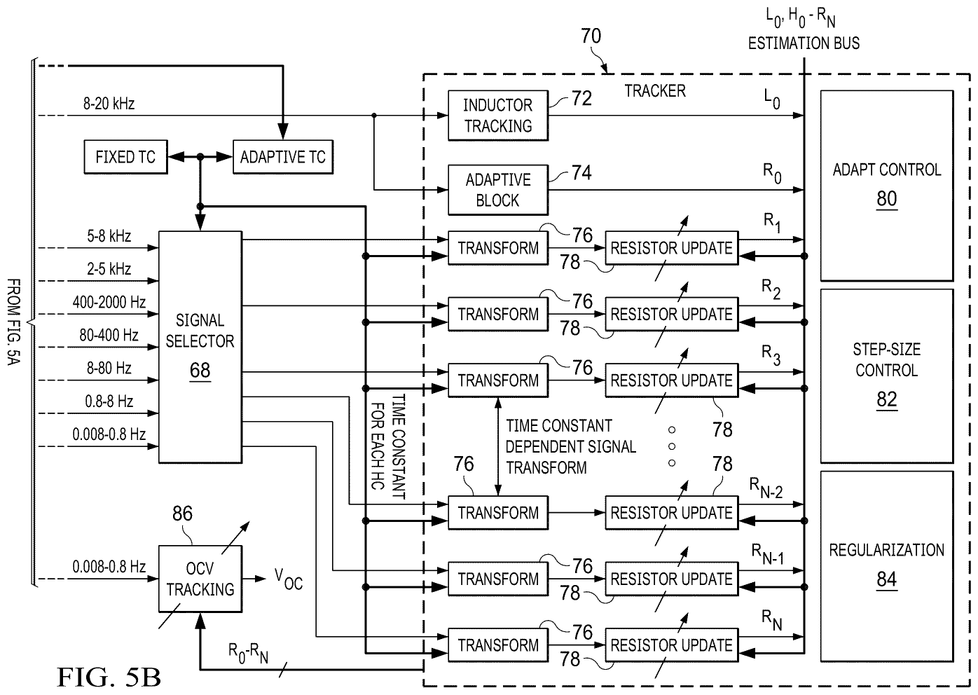

FIGS. 5A and 5B illustrate a block diagram of an example architecture of an algorithm for calculating parameters of an equivalent circuit model of battery 12, in accordance with embodiments of the present disclosure. The functionality of the various blocks depicted in FIGS. 5A and 5B may implement sub-bands 52 and online model estimations 54 shown in FIG. 4.

In accordance with the algorithm depicted in FIGS. 5A and 5B, battery model estimator 24 may measure battery voltage V_{CELL} and battery current I_{CELL}. Battery model estimator 24 may further apply different time constants τ that characterize temporal behaviors of battery 12 to decompose (e.g., with multi-rate filter bank 62) the measured battery voltage V_{CELL} and battery current I_{CELL} into sub-bands 52 based on the different time constants τ. Battery model estimator 24 may also continuously track a resistance R within and associated with each of the sub-bands 52, as well as continuously track open circuit voltage V_{OC} of battery 12. The time constants can either be fixed or estimated dynamically from battery voltage V_{CELL} and battery current I_{CELL}.

As shown in FIGS. 5A and 5B, the example architecture comprises a multi-rate filter bank 62 comprising a plurality of decimators 66, pre-filters 64, a signal selector 68, and a tracker 70 arranged as shown.

Multi-rate filter bank 62 is shown in FIG. 5A as having a full band of 40 kHz, but may have any suitable full band range. Further, decimators 66 may each have a decimation rate as shown in FIG. 5A, but may each have a different decimation rate other than that shown in FIG. 5A. Each decimator 66 may respectively decimate battery voltage V_{CELL} and battery current I_{CELL} signals into low-frequency signals. While specific exemplary frequencies are shown associated with decimators 66, any suitable frequencies may be used. The output of each decimator 66 may be communicated to a respective pre-filter 64, and the output of each pre-filter 64 may represent various sub-bands 52 into which the full band of battery voltage V_{CELL} and battery current I_{CELL} signals is divided. For example, FIG. 5B shows the full band divided into sub-bands of 8-20 kHz, 5-8 kHz, 2-5 kHz, 400-2500 Hz, 800-400 Hz, 8-80 Hz, 0.8-8 Hz, 0.008-0.8 Hz, and 0-0.008 Hz, although any suitable ranges may be used for the various sub-bands 52.

A fixed time constant or an adaptive time constant for each parallel resistive-capacitive section 34 may be received by signal selector 68. A fixed time constant may be based on a set of pre-stored values. An adaptive time constant may be computed dynamically through an adaptive algorithm that uses battery voltage V_{CELL} and battery current I_{CELL} and/or the adaptive time constant may be selected from a look-up table whose indices are selected based on the battery state of charge and/or temperature.

As depicted in FIG. 5B, tracker 70 may perform inductor tracking 72 based on the output of pre-filter 64 representing the highest-frequency sub-band 52 in order to estimate an inductive value Lo (not shown in FIG. 5) that models an equivalent resistance in series with equivalent series resistance 36 of battery 12 and an equivalent circuit model of battery 12. Tracker 70 may also include an adaptive block 74 (e.g., a recursive-least squares, total-least squares, normalized least-mean-squares, total least squares cost function, and/or different variants of gradient descent based algorithms) that outputs resistive value R₀ for the equivalent circuit model of battery 12 based on the output of pre-filter 64 representing the highest-frequency sub-band 52.

The outputs of the remaining pre-filters 64 may be provided as inputs to signal selector 68. As shown in FIGS. 5A and 5B, a plurality of different time constants, which may be distributed such that they cover an entire spectral range of interest and overall time constant value, may be received by signal selector 68. Signal selector 68 may select, for each transform 76/resistor update 78 pair of tracker 70, a signal from an output of pre-filter 64 based on the time constants. In particular, signal selector 68 may select an appropriate signal from multi-rate filter bank 62 such that spectral coverage of the selected signal includes the frequency corresponding to the respective time constant.

Tracker 70 may further include a plurality of transform 76/resistor update 78 pairs that may calculate respective resistive values R₁, . . . , R_{N} of the equivalent circuit model of battery 12. For example, in some embodiments, battery model estimator 24 may calculate respective resistive values R₁, . . . , R_{N} of the equivalent circuit model of battery 12 in a manner similar to that disclosed in U.S. patent application Ser. No. 17/463,980, filed Sep. 1, 2021, and incorporated by reference herein. For example, resistor update blocks 78 may continuously update resistances representing each sub-band 52 using an adaptive algorithm, implemented by adapt control block 80 of tracker 70, using a recursive-least squares, a total-least squares, a normalized least-mean-squares, or other suitable approach. In some embodiments, parameters of the equivalent circuit model of battery 12 may be updated by a resistor update block 78: (a) when a full-band current root-mean-square level is above a threshold, (b) such that a sub-band error is minimized; or (c) jointly such that a full band error is minimized. A learning rate of the update algorithm may be based on a sub-band root-mean-square current level. In some embodiments, resistor update blocks 78 may be constrained to calculate only positive resistance values.

Tracker 70 may also include a step-size control block 82. If the adaptive algorithm implemented by adapt control block 80 includes a family of gradient descent based algorithms, then step-size control block 82 may dynamically calculate the learning rate or step size of such algorithm to ensure faster convergence of the parameters while not drifting away from the true value.

Tracker 70 may also include a regularization block 84. Due to the dynamic nature of the signal and also the varying signal-to-noise ratio conditions, it is important that the adaptive algorithm does not diverge too much from the true solution. Regularization block 84 may avoid the problem of overfitting, which may occur when the adaptive algorithm adapts during low signal-to-noise ratio conditions and tries to minimize the modelling error even though the background noise dominates the signal.

The algorithm may also include an open-circuit voltage (OCV) tracking block 86 configured to adaptively estimate open-circuit voltage V_{OC} based on an input received from pre-filter 64 representing the lowest-frequency sub-band 52 and the various resistive values R₁, . . . , R_{N} of the equivalent circuit model of battery 12. For example, OCV tracking block 86 may, based on the output of the lowest-frequency pre-filter 64 and tracked resistances of the equivalent circuit model for battery 12, continuously update an estimated open-circuit voltage V_{OC} using an adaptive algorithm (e.g., a recursive-least squares, total-least squares, normalized least-mean-squares). In some embodiments, the OCV may be provided by another estimator or algorithm, such as from a fuel gauge solution.

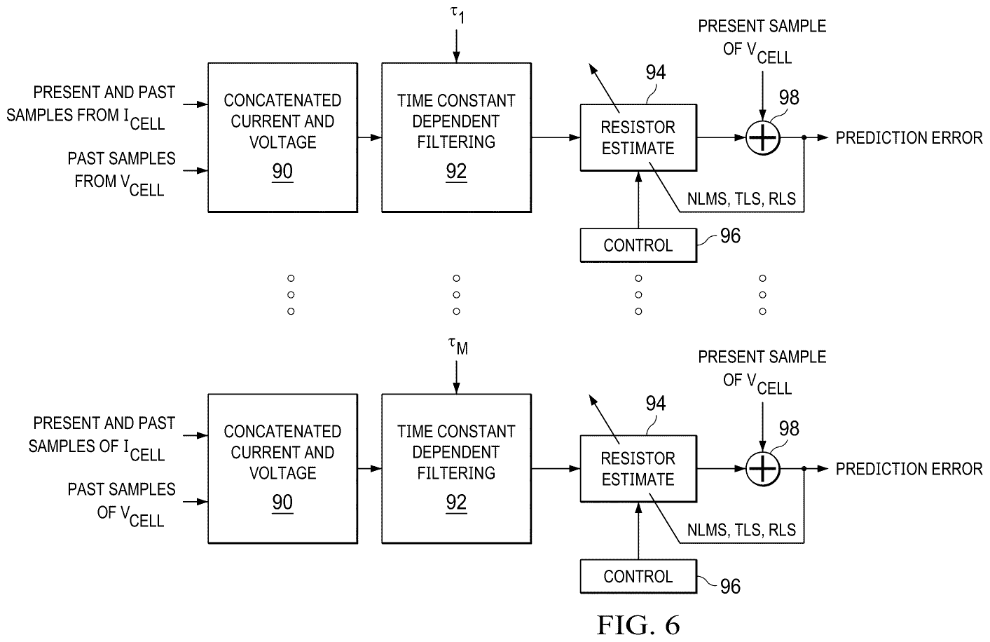

FIG. 6 illustrates a block diagram of an example architecture of tracker 70 for calculating parameters of the equivalent circuit model of battery 12, in accordance with embodiments of the present disclosure. The architecture shown in FIG. 6 may implement transform blocks 76 and resistor update blocks 78 shown in FIGS. 5A and 5B.

FIG. 6 depicts 1 to M number of paths that process battery voltage V_{CELL} and battery current I_{CELL} signals decomposed into sub-bands 52 as described above. Each processing path may include a concatenated current and voltage block 90, time constant dependent filtering block 92, a resistor estimate block 94, a control block 96, and a summer 98 arranged as shown in FIG. 6. Each concatenated current and voltage block 90 may receive as its input the present and past sample values of battery current I_{CELL} and the past sample values of battery voltage V_{CELL} for the given sub-band 52. Time-constant dependent filtering block 92 may receive the output from its respective concatenated current and voltage block 90 and a time constant Ti for the given sub-band 52. Such filtering may be performed in order to convert the non-linear optimization problem into a linear optimization problem. The original equivalent circuit model identification problem involves estimating either resistor and capacitor or resistor and time constant. Estimating them jointly is a non-linear optimization problem, and it is not suited to be done in embedded applications. Therefore, such filtering may simplify the problem into a linear problem by assuming a priori knowledge of the time constants. The time constants can be determined by offline characterization of a battery, or they can be dynamically estimated by a separate time constant estimation block.

Control block 96 may be configured to provide an indication to the adaptive algorithm that the signal conditions are sufficient enough to update the resistive values (e.g., R₁, . . . , R_{N}) of its associated resistor estimate block 94. Each resistor estimate block 94 may provide an estimated present sample of battery voltage V_{CELL} for its respective sub-band 52. Combiner 98 may compare the true sample to the predicted present sample to generate a prediction error. Such prediction error may then be used in the parameter update equation of the adaptive filter. Controller (“CONTROL”) 96 may control an update algorithm to control resistor estimate block 94 to minimize the prediction error.

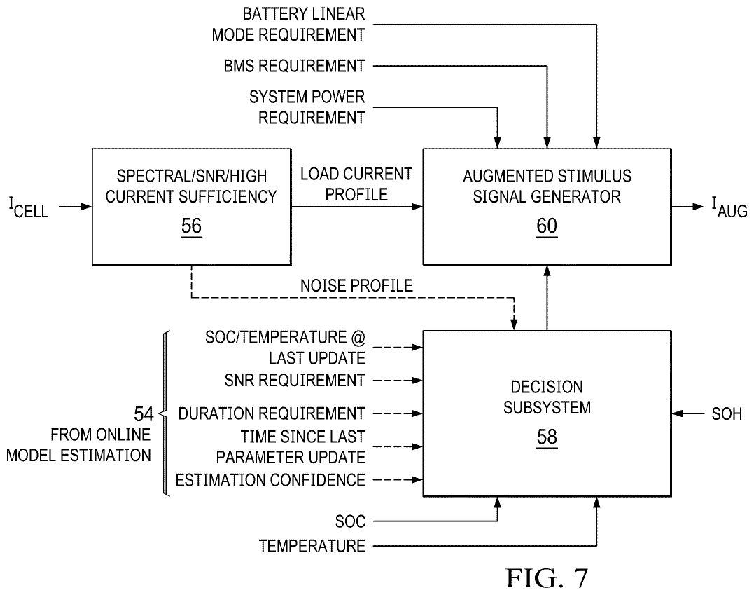

FIG. 7 illustrates a block diagram of selected components of system 50, in accordance with embodiments of the present disclosure. In particular, FIG. 7 depicts more detail demonstrating operability among spectral/SNR sufficiency analysis block 56, decision subsystem 58, and augmented stimulus signal generator 60.

When a system load current is present (e.g., when load 18 draws a current from battery 12), the generation of augmented stimulus in the form of augmented current I_{AUG} may be performed on a sub-band basis. Decision subsystem 58 may determine an aggregate stimulus requirement within each sub-band based on state-of-charge (SOC) and temperature conditions during the last update of model parameters for the respective sub-band compared with prevailing SOC and temperature conditions (i.e., to determine if any changes to SOC and/or temperature have occurred requiring parameter updates). In addition, decision subsystem 58 may also receive a noise profile from spectral/SNR sufficiency analysis block 56, which may continuously evaluate current within each sub-band for spectral sufficiency and noise. Thus, decision subsystem 58 may also determine the aggregate stimulus requirement within each sub-band based on such noise profile, an SNR requirement for the sub-band, a duration of signal required in the sub-band in order to calculate parameters associated with such sub-band (which may vary among sub-bands), an amount of time that has passed since a previous parameter update for the sub-band, and an estimation confidence for the sub-band. For example, spectral/SNR sufficiency analysis block 56 may analyze battery current I_{CELL} to estimate the prevailing SNR in each sub-band, and decision subsystem 58 may use such SNR information to modify a level of stimulus for such sub-band accordingly. Decision subsystem 58 may also determine the aggregate stimulus requirement within each sub-band based on a state of health (SOH) of battery 12. Decision subsystem 58 may also employ one or more power saving schemes in the decision-making process of determining aggregate stimulus requirement. For example, model parameters in some frequency ranges may not change due to SOC and/or temperature changes, and thus, decision subsystem 58 may limit augmented current generation for such sub-bands to conditional triggers other than SOC and/or temperature changes.

Based on the aggregate stimulus requirement determined by decision subsystem 58, a system power requirement, a battery management system requirement, a battery linear mode requirement, and/or other factors, augmented stimulus signal generator 60 may generate augmented current I_{AUG} for each particular sub-band. Generally speaking, augmented stimulus signal generator 60 (in concert with decision subsystem 58) may track absolute current, and if current is above a particular threshold, may cause adaptation of equivalent circuit model parameters to be disabled. However, if an absolute current requirement is not met over time, augmented stimulus signal generator 60 may cause generation of a low-level augmented current I_{AUG} to be generated such that equivalent circuit model parameters are estimated in a linear range of the operating condition of battery 12.

As briefly mentioned above, generation of augmented current I_{AUG} may be conditioned on various factors and conditions. For example, in some embodiments, existence of one or more of the following conditions within a sub-band may be required in order to trigger generation of augmented current I_{AUG} for such sub-band:
A significant change in SOC and the absence of sufficient load current in one of the sub-bands or the full band for a preset period of time;
A significant change in temperature without significant load current in a sub-band or the full band since the last validated update of equivalent circuit model parameters;
Fitting performance of a continuously tracked model has drifted without significant load current in a sub-band or the full band for a preset period of time;
Significant change in root-mean-square value of current over a preset period of time;
A rate of change of averaged battery voltage V_{CELL} significantly changing over a preset period of time; and
Root-mean-square value of current falls below a threshold for a period of time.

The foregoing describes approaches for maintaining and updating parameters of a linear equivalent circuit model 30 for battery 12. However, a battery is a highly dynamic and non-linear system. In addition to temperature, state of charge, and state of health, impedance of a battery may also vary as a function of a current drawn from it. Thus, to ensure accuracy, a battery model may need to be non-linear because the model parameters may also change as a function of current amplitude.

For predictive purposes, equivalent circuit model parameters for a linear model estimated at a certain dynamic load level may not result in accurate voltage prediction when prediction is performed at much higher current levels.

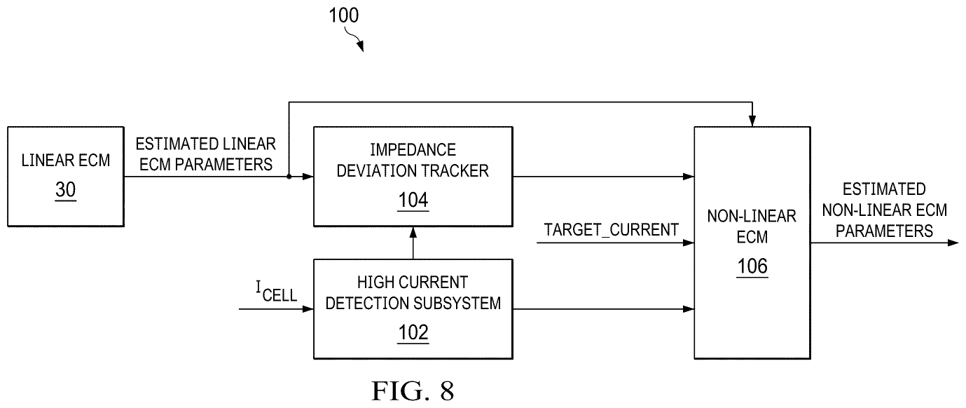

FIG. 8 illustrates a high-level block diagram of selected components of a system 100 for online characterization of a current-dependent non-linear equivalent circuit model of battery 12, in accordance with embodiments of the present disclosure. System 100 may be implemented in whole or part by battery model estimator 24. As shown in FIG. 8, system 100 may include linear equivalent circuit model (ECM) 30, high-current detection subsystem 102, impedance deviation tracker 104, and non-linear ECM 106. In operation of system 100, linear ECM parameters estimated by linear ECM 30 may be converted into current-dependent non-linear ECM parameters by current-dependent non-linear ECM 106.

High current detection subsystem 102 may continuously monitor battery current I_{CELL}. In a typical use case scenario, battery current I_{CELL} may predominantly include long-duration, low-current regions with occasional short-duration, high-current signals that appear in a burst mode. High current detection subsystem 102 may detect these bursty high current events and record the time of these high-current events. In addition, high current detection subsystem 102 may also record the average current during the burst event. Once the high current events are detected, impedance deviation tracker 104 may track quick changes in impedance of battery 12 due to high current events as changes in the resistive-capacitive (RC) pair parameters of linear ECM 30. System 100 may store ECM parameters preceding the high current events and the corresponding average current during the times preceding the high current events for further estimation of non-linear ECM parameters.

As used herein, a “high current event” may occur when an average or root-mean-square value of a discharge current of battery 12 is above a particular threshold (e.g., 2 A) for a pre-specified period of time.

If a high current is not present in the dynamic load for a pre-specified period of time, then a short duration high current may be augmented using augmented current I_{AUG}, and a non-linear impedance deviation may be estimated from this short duration high current pulse, for example in a manner described in U.S. Provisional Patent Application Ser. No. 63/606,389, filed Dec. 5, 2023, which is incorporated by reference herein in its entirety. In some embodiments, such short duration high current may be a direct-current (DC) biased alternating-current (AC) current. In these and other embodiments, the duration of the short duration high current may be controllable.

Impedance deviation tracker 104 may estimate changes in the RC-pair impedances of linear ECM 30 by computing the difference between the impedance estimated during the high current event and the impedance estimated during the time preceding the high current event. Impedance deviation tracker 104 may continuously monitor and store the changes in the impedance and the corresponding high current average value.

Non-linear ECM 106 may continuously estimate an online interpolating curve from all the measurement sets in order to interpolate/extrapolate changes in the impedance at current amplitudes that are in the range outside of the measurement set. Thus, this interpolating function may be continuously modified in an online manner to account for changes due to variations in battery state of charge, temperature, and state of health. Non-linear ECM 106 may also combine the current dependent resistance change with the RC-pair impedance that is estimated by linear ECM 30 during non-high current events to obtain a current dependent non-linear ECM parameter set.

As shown in FIG. 8, non-linear ECM 106 receives a signal TARGET_CURRENT as an input. To illustrate, if an impedance spectral function for battery 12 is represented as Z(f) where f is the frequency, then Z(f) is typically a linear impedance function wherein the impedance function does not change as a function of input current level. However, as described herein, battery 12 is a non-linear system. Therefore, non-linear ECM 106 may approximate the non-linear impedance function as a current-dependent impedance function represented as Z(f,I), where I is represented by signal TARGET_CURRENT. Thus, for a given input current level, non-linear ECM 106 may have a corresponding impedance function.

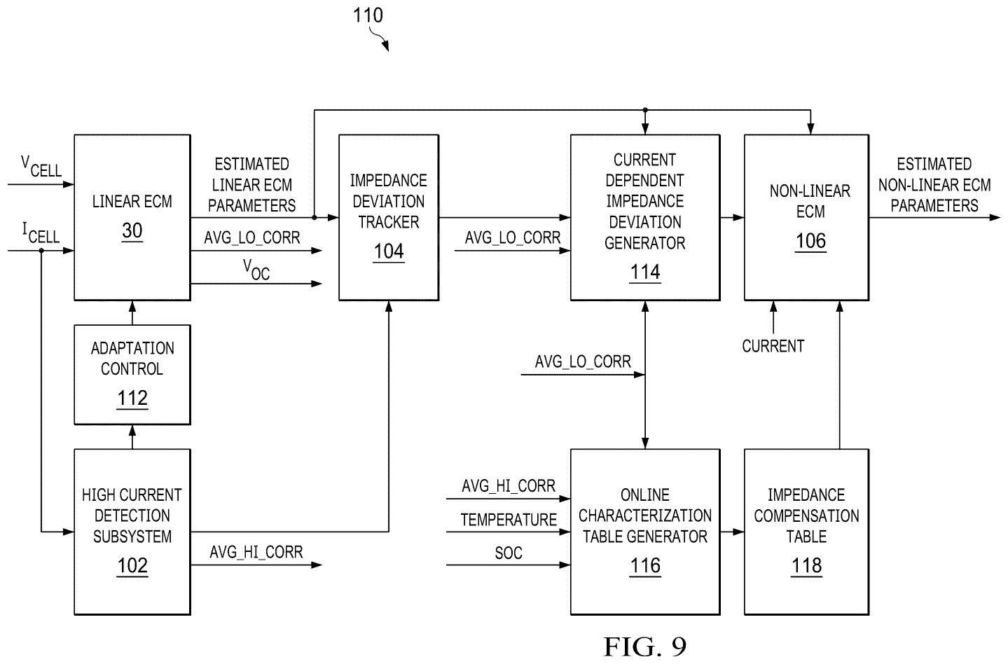

FIG. 9 illustrates a detailed-level block diagram of selected components of a system 110 for online characterization of a current-dependent non-linear equivalent circuit model of battery 12, in accordance with embodiments of the present disclosure. In some embodiments, system 110 may be used to implement system 100 depicted in FIG. 8.

As shown in FIG. 9, system 110 may include linear ECM 30, high current detection subsystem 102, impedance deviation tracker 104, non-linear ECM 106, adaptation controller (“ADAPTATION CONTROL”) 112, current-dependent impedance deviation generator 114, online characterization table generator 116, and impedance compensation table 118.

In operation of system 110, linear ECM parameters estimated by linear ECM 30 may be converted into current-dependent non-linear ECM 106 which may output non-linear ECM parameters. In addition to linear ECM parameters, linear ECM 30 may also output an average current AVG_LO_CURR and battery open-circuit voltage V_{OC}.

As above, high current detection subsystem 102 may continuously monitor battery current I_{CELL} and detect and record high current events. In addition, high current detection subsystem 102 may also record the average current AVG_HI_CURR during the burst event. Via adaptation controller 112, changes in RC-pair parameters of linear ECM 30 may occur in response to the high current events, and impedance deviation tracker 104 may track quick changes in impedance of battery 12 due to high current events as changes in the RC-pair parameters of linear ECM 30. In some embodiments, adaptation controller 112 may modify an adaptation rate of linear ECM 30 when a high current event is detected.

Impedance deviation tracker 104 may estimate changes in the RC-pair impedances of linear ECM 30 by computing the difference between the impedance estimated during the high current event and the impedance estimated during the time preceding the high current event.

Based on average current AVG_HI_CURR during the burst event, the average current AVG_LO_CURR preceding the burst event, deviations calculated by impedance deviation tracker 104, and linear ECM 30 parameters, current dependent deviation impedance deviation generator 114 may continuously estimate an online interpolating curve from all the measurement sets in order to interpolate/extrapolate changes in the impedance at current amplitudes that are in the range outside of the measurement set.

System 110 may store ECM parameters preceding the high current events and the corresponding average current during the times preceding the high current events for further estimation of non-linear ECM parameters. System 110 may also continuously monitor and store the changes in the impedance and the corresponding high current average value.

Online characterization table generator 116 may continuously update impedance compensation table 118 (e.g., a lookup table) to store and continuously modify impedance compensation values due to variations in battery state of charge, temperature, and state of health.

Non-linear ECM 106 may also combine the current dependent resistance change with the RC-pair impedance that is estimated by linear ECM 30 during non-high current events, and based on information from other components of system 110, obtain a current dependent non-linear ECM parameter set.

To further illustrate the functionality of FIG. 9 in generating impedance compensation table 118, impedance compensation table 118 may be maintained at a set of SOCs (e.g., for every 5% SOC) and temperature (e.g., every 5°). An example of impedance compensation table 118 is set forth below.

| Current\Resistance | ΔR₀ | ΔR₁ | ΔR₂ | | ΔR_{N} |
|---|---|---|---|---|---|
| of RC pair | (Ω) | (Ω) | (Ω) | ... ... ... .... | (Ω) |
| 2 A | | | | | |
| 2.1 A | | | | | |
| : | | | | | |
| : | | | | | |
| 20 A | | | | | |

At a given time instant with a prevailing SOC and temperature, the non-linear ECM block 106 takes the current independent linear ECM parameters as input and adjusts the corresponding linear ECM parameters using the compensation value stored in the online characterization table. For example, for an ECM model, impedance compensation table 118 may include resistance/capacitance compensation values.

To further illustrate, if impedance at a particular TARGET_CURRENT is given as:

$${R}_{i} ( TARGET\_CURRENT ) = {R}_{i} ( Linear ECM ) - Δ {R}_{i} ( TARGET\_CURRENT , SOC , Temp )$$

then the overall current dependent impedance may be calculated as:

$$Z ( ω , TARGET\_CURRENT ) = {R}_{0} ( TARGET\_CURRENT ) + {\sum }_{m = 1}^{M} \frac{{R}_{m} ( TARGET\_CURRENT}{1 + j ω {R}_{m} ( TARGET\_CURRENT ) {C}_{m}}$$

Thus, non-linear ECM 106 may provide a set of current dependent ECM parameters at the prevailing SOC and temperature.

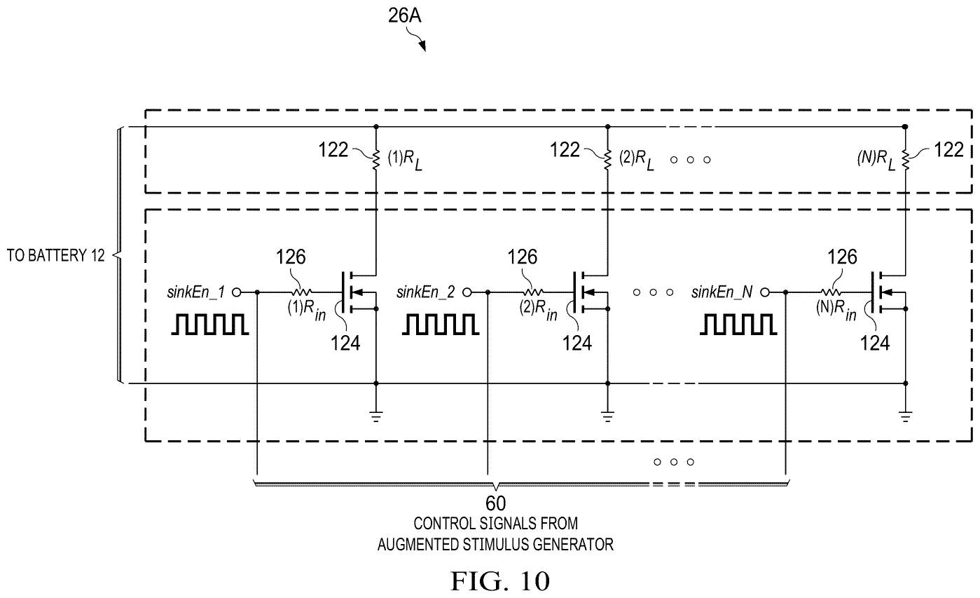

FIG. 10 illustrates a circuit diagram of selected components of a subsystem 26A for generating augmented current I_{AUG}, in accordance with embodiments of the present disclosure. In some embodiments, subsystem 26A as depicted in FIG. 10 may be used to implement dependent current source 26.

As shown in FIG. 10, subsystem 26A may include a plurality of parallel resistors 122 each controlled by a respective switch 124. In some embodiments, switches 124 (and their respective bias resistors 126 coupled to their respective gate terminals) may be located on the same die as battery monitoring circuitry 20, while resistors 122 may each be discrete components external to such die. In operation, augmented stimulus signal generator 60 may generate a plurality of control signals for selectively enabling (e.g., activating, turning on, closing, etc.) and disabling (e.g., deactivating, turning off, opening, etc.) switches 124, such that a sum of individual currents flowing through switches 122 is equal to the desired augmented current I_{AUG}. The switch control for the various switches 124 may be programmed to generate a desired AC load current.

In some embodiments, augmented stimulus signal generator 60 may trigger subsystem 26A to generate augmented current I_{AUG} after a passage of a period of time since parameters of battery model estimator 24 were last updated. In these and other embodiments, augmented stimulus signal generator 60 may trigger subsystem 26A to generate augmented current I_{AUG} in response to spectral/SNR sufficiency analysis 56 indicating an insufficiency of battery current I_{CELL} needed to perform estimation of parameters of battery model estimator 24.

In some embodiments, augmented current I_{AUG} may be different depending on various operating conditions (e.g., SOC, SOC, SOH, temperature), in order to prevent brownout, as discussed above. In such embodiments augmented stimulus signal generator 60 may be configured to adjust a varying level of augmented current I_{AUG} by controlling an amount of current through each resistor 122 with a switching signal to each switch 124. For example, augmented stimulus signal generator 60 may drive pulse-width modulated signals for controlling switches 124, wherein the switching frequencies may control augmented current I_{AUG} over the entire pulse width of augmented current I_{AUG}. The peak current amplitude through each resistor 122 may be determined by its resistance value, and the safe operating limits in terms of heat dissipation through resistors 122 may be determined during system design.

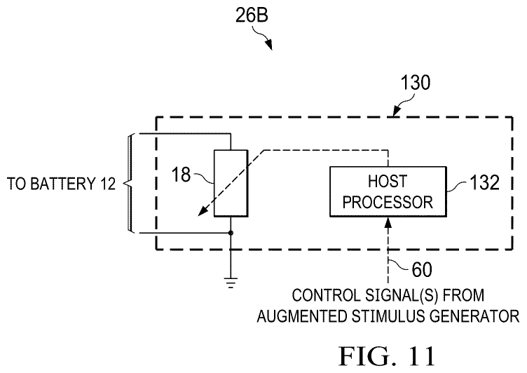

FIG. 11 illustrates a circuit diagram of selected components of a subsystem 26B for generating augmented current I_{AUG}, in accordance with embodiments of the present disclosure. In some embodiments, subsystem 26B as depicted in FIG. 11 may be used to implement the functionality of dependent current source 26, albeit with such functionality embedded within load 18 of power delivery network 10.

As shown in FIG. 11, augmented stimulus signal generator 60 may communicate one or more control signals to a host processor 132 of a device 130 comprising load 18, wherein such one or more control signals are indicative of the desired augmented current I_{AUG}. In response, host processor 132 may control one or more processes, uses, and/or components of load 18 such that load 18 draws the desired augmented current I_{AUG} from battery 12 (e.g., in addition to any load current required for load 18). For example, to generate such additional augmented current I_{AUG} from battery 12, subsystem 26B may increase electrical power to one or more components of load 18, such as increasing a brightness of a display of device 130, causing a process of load 18 to execute “dummy” cycles that consume power, and/or any other suitable power-increasing event.

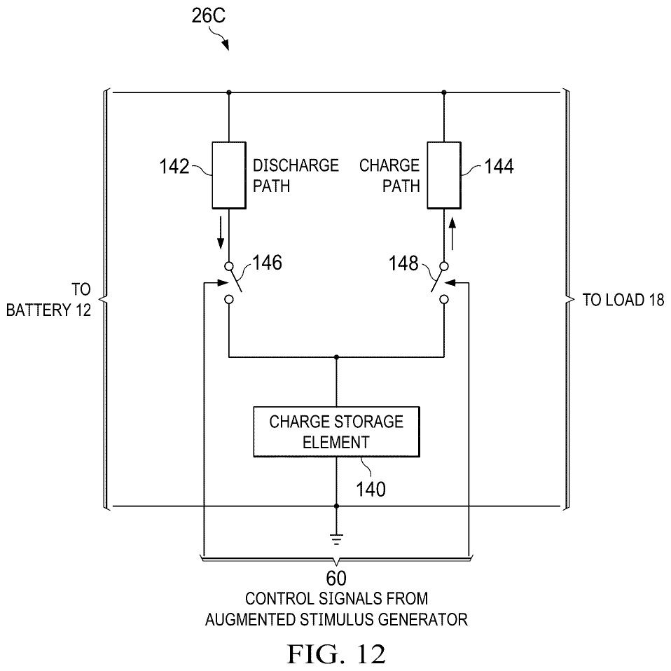

FIG. 12 illustrates a circuit diagram of selected components of a subsystem 26C for generating augmented current I_{AUG}, in accordance with embodiments of the present disclosure. In some embodiments, subsystem 26C as depicted in FIG. 12 may be used to implement dependent current source 26.

As shown in FIG. 12, subsystem 26C may comprise a charge storage element 140, which may include a capacitor, another battery, and/or any other suitable device for storing electrical energy. Further, subsystem 26C may include a discharge path 142 that may discharge energy from battery 12 to charge storage element 140 when switch 146 is enabled, and a charge path 144 that may charge battery 12 from charge storage element 140 when switch 148 is enabled. Thus, when augmented current I_{AUG} is desired, augmented stimulus signal generator 60 may generate a control signal to enable switch 146 (and disable switch 148) such that the desired augmented current I_{AUG} is generated and discharges battery 12 to charge storage element 140 in accordance with augmented current I_{AUG}. Likewise, when augmented current I_{AUG} is not desired, augmented stimulus signal generator 60 may generate a control signal to enable switch 148 (and disable switch 146) such that battery 12 is recharged from charge storage element 140, allowing reuse of the electrical energy used to generate augmented current I_{AUG}, and minimizing power loss associated with generation of augmented current I_{AUG}. In some embodiments, in lieu of battery 12 recharging from charge storage element 140 via charge path 144, electrical energy may be used to generate additional current to load 18 in order to supplement any current provided by battery 12 to load 18.

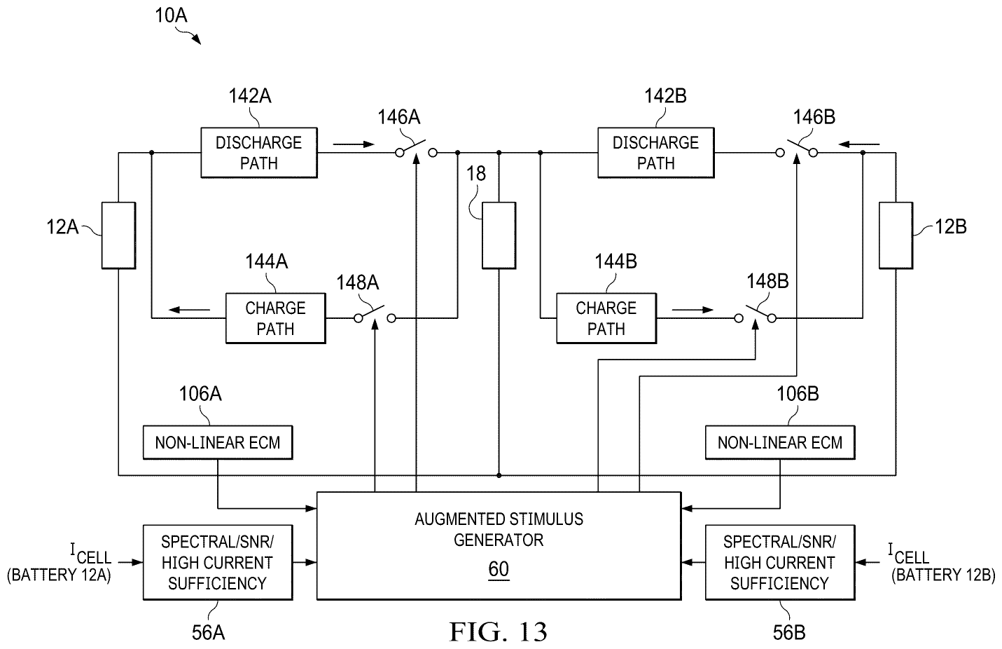

FIG. 13 illustrates a block diagram of selected components of an example power delivery network 10A, in accordance with embodiments of the present disclosure. Power delivery network 10A may be considered an extension of subsystem 26C depicted in FIG. 12, in the sense that charge storage element 140 of subsystem 26C is implemented as another battery and an additional charge path and discharge path, so that both batteries may be selectively charged and discharged to one another in order to generate a respective augmented current I_{AUG} for each battery, when desired. This application may lend well for systems that include multiple cells (e.g., a laptop computer, electrical vehicle, etc.).

Thus, as shown in FIG. 13, augmented stimulus signal generator 60 may, based on results provided by spectral/SNR sufficiency analysis 56A and a non-linear ECM 106A for a first battery (or battery cell) 12A and/or results provided by spectral/SNR sufficiency analysis 56B and a non-linear ECM 106B for a second battery (or battery cell) 12B, may determine if an augmented current I_{AUG} is desired from either of battery 12A or 12B. For example, if an augmented current I_{AUG} is desired to be drawn from battery 12A, augmented stimulus signal generator 60 may appropriately control switches 146A, 146B, 148A, and 148B to cause such augmented current I_{AUG} to discharge battery 12A via discharge path 142A and charge battery 12B via charge path 144B. Likewise, if an augmented current I_{AUG} is desired to be drawn from battery 12B, augmented stimulus signal generator 60 may appropriately control switches 146A, 146B, 148A, and 148B to cause such augmented current I_{AUG} to discharge battery 12B via discharge path 142B and charge battery 12A via charge path 144A.

Impedance of a battery 12 may vary due to various operating conditions, including without limitation SOC, temperature, battery age, and/or other reasons. Accordingly, it may not be optimal for augmented stimulus signal generator 60 to generate a fixed augmented current I_{AUG}. Depending on the state of battery 12 and operating conditions, a fixed-amplitude current pulse for augmented current I_{AUG} may cause battery voltage V_{CELL} to drop below a brownout threshold level. Thus, an allowable duration and amplitude of an augmented pulse may vary due to SOC, temperature, battery age, and/or other reasons. Accordingly, to overcome these potential problems, augmented stimulus signal generator 60 or another component of system 50/battery model estimator 24 may further be configured to estimate a duration and an amplitude of a valid signal for augmented current I_{AUG} that prevents brownout. Thus, augmented stimulus signal generator 60 or another component may dynamically calculate an allowable duration and amplitude for augmented current I_{AUG} based on prevailing load current levels and other operating conditions.

To dynamically estimate such allowable duration and amplitude for augmented current I_{AUG}, augmented stimulus signal generator 60 may use either linear or non-linear ECM parameters to estimate safe limits with respect to pulse duration and amplitude for augmented current I_{AUG}. In some embodiments, if non-linear ECM 106 is not available or has not been recently updated, then augmented stimulus signal generator 60 may use parameters from linear ECM 30.

To illustrate, referring back to linear ECM 30 shown in FIG. 3, a predicted output for battery voltage V_{CELL} may be given as:

$${\tilde{V}}_{CELL} ( {t}_{p} ) = OCV ( {t}_{p} ) - {I}_{p}^{( {t}_{p} )} {R}_{o} - {\sum }_{m = 1}^{M} {R}_{m} ( {I}_{p}^{( {t}_{p} )} ) [ {I}_{m} {e}^{- {t}_{p} / {TC}_{m}} + {I}_{p}^{( {t}_{p} )} ( 1 - {e}^{- {t}_{p} / {TC}_{m}} ) ]$$

where tₚ is a pulse duration for augmented current I_{AUG}, TCₘ is a time constant of the mth resistive-capacitive pair of linear ECM 30, Iₚ is a to-be-determined pulse amplitude for augmented current I_{AUG} that ensures voltage V_{CELL} remains above a brownout threshold V_{bo}(tₚ) (wherein pulse amplitude Iₚ may include an average or root-mean-square current signal, and may include a pulse or any complex waveform), Rₘ is a linear ECM resistance of the mth resistive-capacitive pair of linear ECM 30, Rₘ(Iₚ^{(t}^{ₚ}⁾) is a current dependent non-linear ECM resistance of mth resistive-capacitive pair of linear ECM 30, Iₘ is a current through the mth resistive-capacitive pair (which may include history of past current samples), V_{bo}(tₚ) is a preset brownout voltage for a given pulse duration, OCV(tₚ) is an open circuit voltage at the end of the pulse duration (e.g., which may be calculated starting with an OCV estimate just before the pulse augmentation using Coulomb counting to estimate OCV at the end of the augmented pulse for a given constant current Iₚ^{(t}^{ₚ}⁾).

For a given pulse duration tₚ, Iₚ^{(t}^{ₚ}⁾ may be solved in closed form if parameters of linear ECM 30 are used. In such instance, resistance Rₘ is independent of pulse amplitude Iₚ^{(t}^{ₚ}⁾).

If parameters of non-linear ECM 106 are used, wherein resistance Rₘ is dependent on pulse amplitude Iₚ^{(t}^{ₚ}⁾), then augmented stimulus signal generator 60 may use an iterative search algorithm (e.g., a bisection algorithm) to determine pulse amplitude Iₚ^{(t}^{ₚ}⁾.

Solving for the foregoing equation, augmented stimulus signal generator 60 may determine a set of valid (tₚ, Iₚ^{(t}^{ₚ}⁾). This valid set may be used by augmented stimulus signal generator 60 to generate augmented current I_{AUG} that ensures that brownout threshold V_{bo}(tₚ) is not reached during augmentation.

In the foregoing approach, a valid set may be determined assuming that a prevailing load (e.g., current drawn by load 18) will not cause brownout threshold V_{bo}(tₚ) to be exceeded, a current tolerance may be added to pulse amplitude Iₚ^{(t}^{ₚ}⁾. In addition or alternatively, pulse augmentation may be enabled only when the prevailing load current is zero or otherwise below a very low threshold.

Embodiments of the present disclosure thus provide methods and systems to estimate current dependent non-linear equivalent circuit model (ECM) parameters of a battery in a system configured to provide a load. A sense current and a terminal voltage of a battery may be measured, and different time constants that characterize temporal behaviors of the battery may be obtained and/or used. The ECM may be comprised of a set of N number of RC pairs wherein N is an integer equal to one or greater. The RC pair values may be estimated by reducing an error between the terminal voltage and the fitted voltage. In one embodiment, the time constants of each RC pair may be chosen a priori and only the resistance of each RC pair may be estimated using an adaptive algorithm. In another embodiment, the current and voltage may be decomposed into sub-bands, and the resistance of each RC pair may be continuously tracked within each sub-band. An open circuit voltage of the battery may also be continuously tracked.

Linear ECM parameters may be derived to model a linear ECM by using multiple RC-elements with different time constants that characterize temporal behaviors of the battery. A sense current may be continuously monitored to detect high current events. A deviation for each RC-pair impedance during the high current events may be continuously tracked. Non-linear online ECM parameters may be derived using the linear ECM parameters and the RC-pair impedance deviations at all current amplitudes.

The RC-pair impedance deviations at all current levels may be interpolated and/or extrapolated from RC-pair impedance deviations computed during the low current regions and the detected high current regions. The impedance deviations at all current amplitudes may be interpolated and/or extrapolated using different variants of non-linear mapping functions. The RC-pair impedance and the impedance deviations may be calculated using an adaptive algorithm. The method may be an adaptive algorithm, and an adaptation rate of the adaptive algorithm may be dynamically changed whenever the high current region is detected. The tracked deviations at different high current amplitudes from past time samples from the continuous tracking of a deviation step may be stored and then used during an interpolation/extrapolation step. The high current regions may be detected whenever a root-mean-square (RMS) current and/or a maximum instantaneous current are above some thresholds.

The current dependent non-linear ECM parameters may be used to determine available power that the battery is able to support for a sustained period of time before the terminal voltage of the battery reaches a pre-determined brown-out voltage. The current dependent non-linear ECM parameters may be used to determine a maximum current that is able to be drawn from the battery for a sustained period of time before the terminal voltage of the battery reaches a pre-determined brown-out voltage. The current dependent non-linear ECM parameters may be used to determine available energy that the battery is able to sustain before the terminal voltage of the battery reaches a pre-determined brown-out voltage. The different time constants may be continuously tracked. The continuous tracking of the impedance may be accomplished by using an adaptive algorithm such as a Normalized Least Means Square (NLMS) algorithm, a Total Least Squares (TLS) algorithm, or a Recursive Least Squares (RLS) algorithm. A load current drawn by the load may be used as the sense current.

In accordance with the systems and methods disclosed herein, an augmented current I_{AUG} may be generated through a distributed load. In some embodiments, the distributed load may comprise a bank of passive circuit elements such as resistors (e.g., resistors 122) for example as shown in FIG. 10. Augmented current I_{AUG} may be controlled by dynamically controlling the bank of passive circuit elements. The distributed system load may be augmented through momentarily increased current usage of the system/device that distributes a load current across different power consuming processes within the system/device. In some embodiments, the high current requirement may be met by the distribution of load current through a combination of existing load current, augmented current, load through resistive load, and a host processor controlled system load.

The distributed system load may be controlled by a host processor. A battery impedance model parameter estimator system may request a high current load to the host processor through an interface, for example as shown in FIG. 11.

A distributed load may be augmented by drawing a high current by a temporary charging element as shown in FIG. 12. A charge stored in the temporary charging element may be stored and the charge is transferred back into the battery. The system may be a multi-cell system, or the system may comprise multiple batteries/cells as shown in FIG. 13. A high current may be drawn from one of the multiple batteries/cells, and a charge may be stored in another of the multiple batteries/cells in the multi-cell system. The stored charge may be transferred back to a battery/cell where the high current was drawn from or to other batteries/cells in the multi-cell system.

Each cell behavior may be modelled by a separate non-linear ECM, and the high current may be drawn as per the requirement of each non-linear ECM. A current for the augmented load may be generated through different types of short duration load current pulses.

The impedance model may be an equivalent circuit model that contains different resistor-capacitor (RC) pairs with respective time constants. The impedances of the RC pairs may be continuously updated when a high current is not detected during the continuously monitoring sense current step. The impedances may be calculated using an adaptive algorithm. The RC-pair impedance deviation may be estimated when the high current load is augmented. The impedance deviations may be calculated using an adaptive algorithm. A high current region may be detected whenever a root-mean-square (RMS) current and/or a maximum instantaneous current are above some thresholds. The non-linear impedance model parameters may be used to determine available power the battery can support before a terminal voltage of the battery reaches a pre-determined brown-out voltage.

The non-linear impedance model parameters may be used to determine a maximum current or power that may be drawn from the battery over a period of time before a terminal voltage of the battery reaches a pre-determined brown-out voltage. The non-linear impedance model parameters may be used to determine available energy the battery can sustain before a terminal voltage of the battery reaches a pre-determined brown-out voltage. The non-linear impedance parameters measured at different augmented current levels may be stored and an online look-up table that is a function of different current levels may be generated. The look-up table may be used to update the non-linear impedance parameters when high current augmentation is not possible. The look-up table may be a function of SOC, SOH, temperature, and/or a current level.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method for estimating current-dependent non-linear equivalent circuit model (ECM) parameters of a battery, comprising:
measuring a battery voltage across terminals of the battery and a battery current drawn from the battery;
modelling behavior of the battery with an impedance model having impedance model parameters;
dynamically analyzing the battery current drawn from the battery by a load;
dynamically determining safe operating limits for an augmented current for augmenting the current drawn by the load;
based on analysis of the battery current and the safe operating limits, determining the augmented current;
generating the augmented current to be drawn from the battery; and
estimating the impedance model parameters when the augmented current is drawn from the battery.

2. The method of claim 1, wherein generating the augmented current comprises generating the augmented current through a distributed load network.

3. The method of claim 2, wherein the distributed load network comprises a plurality of passive circuit elements.

4. The method of claim 3, further comprising controlling the augmented current by selectively enabling one or more of the plurality of passive circuit elements and selectively disabling another one or more of the plurality of passive circuit elements.

5. The method of claim 3, wherein the passive circuit elements comprise resistors.

6. The method of claim 1, wherein generating the augmented current comprises increasing a current delivered to a system load powered from the battery.

7. The method of claim 6, wherein the system load is controlled by a host processor.

8. The method of claim 7, wherein generating the augmented current comprises communicating a request to the host processor, via an interface, to increase the current delivered to the system load.

9. The method of claim 1, wherein generating the augmented current comprises discharging the battery into a charge storage element.

10. The method of claim 9, further comprising recharging the battery from the charge storage element.

11. The method of claim 1, wherein generating the augmented current comprises discharging the battery into another battery in a multi-cell system.

12. The method of claim 1, wherein the augmented current is a short-duration high level constant current.

13. The method of claim 1, wherein the augmented current is a short-duration high level direct-current biased alternating current.

14. The method of claim 1, further comprising controlling a duration of the augmented current.

15. The method of claim 1, wherein generating the augmented current comprises discharging the battery into a second battery.

16. The method of claim 15, further comprising recharging the battery from the second battery.

17. The method of claim 15, further comprising:
measuring a second battery voltage across terminals of the second battery and a second battery current drawn from the second battery;
modelling behavior of the second battery with a second impedance model having second impedance model parameters;
dynamically analyzing the second battery current drawn from the second battery by the load;
based on analysis of the second battery current, determining a second augmented current for augmenting the second current drawn by the load;
generating the second augmented current to be drawn from the battery by discharging the second battery into the first battery; and
estimating the second impedance model parameters when the second augmented current is drawn from the second battery.

18. The method of claim 15, further comprising supplying the augmented current into the second battery to the load.

19. The method of claim 1, wherein the safe operating limits comprise an amplitude and a duration of the augmented current determined based on the impedance model parameters.

20. The method of claim 1, wherein safe operating limits for the augmented current are based on a brownout voltage for the battery voltage.

21. The method of claim 1, wherein the augmented current is generated when the battery current drawn from the battery by the load is below a threshold.

22. A system for estimating current-dependent non-linear equivalent circuit model (ECM) parameters of a battery, comprising:
measurement circuitry for measuring a battery voltage across terminals of the battery and a battery current drawn from the battery;
an impedance model having impedance model parameters, the impedance model for modelling behavior of the battery;
an augmented stimulus signal generator configured to:
dynamically analyze the battery current drawn from the battery by a load;
dynamically determine safe operating limits for an augmented current for augmenting the current drawn by the load;
based on analysis of the battery current and the safe operating limits, determine the augmented current; and
generate the augmented current to be drawn from the battery; and
a battery model estimator for estimating the impedance model parameters when the augmented current is drawn from the battery.

23. The system of claim 22, wherein generating the augmented current comprises generating the augmented current through a distributed load network.

24. The system of claim 23, wherein the distributed load network comprises a plurality of passive circuit elements.

25. The system of claim 24, further comprising control circuitry for controlling the augmented current by selectively enabling one or more of the plurality of passive circuit elements and selectively disabling another one or more of the plurality of passive circuit elements.

26. The system of claim 24, wherein the passive circuit elements comprise resistors.

27. The system of claim 22, wherein generating the augmented current comprises increasing a current delivered to a system load powered from the battery.

28. The system of claim 27, further comprising a host processor for controlling the system load.

29. The system of claim 28, wherein generating the augmented current comprises communicating a request to the host processor, via an interface, to increase the current delivered to the system load.

30. The system of claim 22, wherein generating the augmented current comprises discharging the battery into a charge storage element.

31. The system of claim 30, further comprising charging circuitry for recharging the battery from the charge storage element.

32. The system of claim 22, wherein generating the augmented current comprises discharging the battery into another battery in a multi-cell system.

33. The system of claim 22, wherein the augmented current is a short-duration high level constant current.

34. The system of claim 22, wherein the augmented current is a short-duration high level direct-current biased alternating current.

35. The system of claim 22, wherein the augmented stimulus signal generator is further configured to control a duration of the augmented current.

36. The system of claim 22, wherein generating the augmented current comprises discharging the battery into a second battery.

37. The system of claim 36, further comprising charging circuitry for recharging the battery from the second battery.

38. The system of claim 36, further comprising a second impedance model having second impedance model parameters, the second impedance model for modelling behavior of a second battery, and wherein:
the measurement circuitry is further configured to measure a second battery voltage across terminals of the second battery and a second battery current drawn from the second battery;
the augmented stimulus signal generator is further configured to:
dynamically analyze the second battery current drawn from the second battery by the load;
based on analysis of the second battery current, determine a second augmented current for augmenting the second current drawn by the load; and
generate the second augmented current to be drawn from the battery by discharging the second battery into the first battery; and
the battery model estimator is further configured to estimate the second impedance model parameters when the second augmented current is drawn from the second battery.

39. The system of claim 36, wherein the augmented stimulus signal generator is further configured to supply the augmented current into the second battery to the load.

40. The system of claim 22, wherein the safe operating limits comprise an amplitude and a duration of the augmented current determined based on the impedance model parameters.

41. The system of claim 22, wherein safe operating limits for the augmented current are based on a brownout voltage for the battery voltage.

42. The system of claim 22, wherein the augmented current is generated when the battery current drawn from the battery by the load is below a threshold.
